(19) United States
(12) Patent Application Publication
(10) Pub. No.: US 2026/0251705 A1
(43) Pub. Date: Aug. 27, 2026

(54) Electron Beam Application Device and Time Constant Measurement Method

(71) Applicant: Hitachi High-Tech Corporation, Minato-ku, Tokyo (JP)

(72) Inventors: Hideo MORISHITA, Tokyo (JP); Yoichi OSE, Tokyo (JP); Tsutomu SAITO, Tokyo (JP); Takashi OHSHIMA, Tokyo (JP); Daichi TAKANE, Tokyo (JP)

(21) Appl. No.: 19/161,356

(22) PCT Filed: Jun. 13, 2023
(86) PCT No.: PCT/JP2023/021825

§ 371 Date: Sep. 2, 2025

(51) Int. Cl. G01R 31/305

(52) U.S. Cl. CPC G01R 31/305

(57) ABSTRACT

This electron beam application device includes: an electron optical system for focusing, on a sample 11, a pulse electron beam 7 emitted from a pulse electron gun 25 having a photocathode; a detector 14 for detecting signal electrons 41 emitted when the sample is irradiated with the pulse electron beam; a probe 15 capable of coming into contact with a measurement region of the sample; a voltage source 17 for applying a periodically varying sample voltage to the sample via the probe; and a timing controller 18 for synchronously controlling the voltage source and the pulse electron gun and for controlling the timing of the irradiation with the pulse electron beam in one period of the sample voltage. The electron beam application device calculates a time constant of the measurement region of the sample on the basis of a detection signal amount resulting from the detector detecting signal electrons emitted when the measurement region to which the sample voltage is applied is irradiated with the pulse electron beam.

### TECHNICAL FIELD

The present invention relates to an electron beam application device and a time constant measurement method using the same.

### BACKGROUND ART

A probing system capable of measuring electrical characteristics is used for defect analysis and failure analysis of a semiconductor device. The quality of the device is determined on the basis of a measurement result of electrical characteristics of a local region. PTL 1 discloses a technique of bringing a probe for measurement into contact with a wiring region of a semiconductor device sample to measure electrical characteristics thereof, and detecting disconnection or defect occurring in the wiring portion to determine the quality. Specifically, a sine voltage of a frequency f is applied from the back side of the semiconductor substrate, and the variation in time of the voltage of the wiring region on the front side is measured. The measured voltage of the wiring region has a sine waveform whose phase changes at the same frequency f as the voltage applied from the back side, and a change in the resistance value due to disconnection or defect of the wiring portion is reflected in a phase change 0. Therefore, the quality of the wiring portion can be determined on the basis of the phase change 0. For measuring the variation in time of the voltage of the wiring region on the front side, an example using a probe and an example using a pulse electron beam are disclosed. The latter case uses a scanning electron microscope (SEM), which pulses an electron beam to irradiate and scan the sample, detects emitted electrons, and displays the signal intensity of each irradiated point. Information on the surface voltage of the sample can be obtained by detecting secondary electrons (SE) that are emitted from the sample and have energy of about 10 eV or less.

### CITATION LIST

### Patent Literature

PTL 1: JP2005-85806A

### SUMMARY OF INVENTION

### Technical Problem

PTL 1 uses a strobe waveform mode of an electron microscope to measure the variation in time of the voltage of the wiring region using a pulse electron beam. In the strobe waveform mode, the sample is irradiated with the pulse electron beam only at a specific phase synchronized with the frequency of the voltage applied to the sample (the back surface of the semiconductor substrate in PTL 1). This can reduce the irradiation beam diameter of the electron beam to about 1 nm under optimum conditions, thereby achieving advanced miniaturization and complication, and thus can be an advantageous measurement method for the measurement of the electrical characteristics of a device structure that is difficult for a probe to come into contact with.

However, if a general thermionic emission electron source, field emission electron source, or Schottky emission electron source is used as the electron source of the electron microscope, the pulsing of the electron beam is performed by chopping an electron beam continuously emitted from the electron source by a blanker. Therefore, as the voltage applied to the sample becomes higher in frequency, the blanker needs to chop the electron beam at a higher speed. For this purpose, the diameter of an aperture for the electron beam to pass through needs to be reduced to enable chopping by slight deflection of the electron beam. Therefore, the irradiation current amount of the pulse electron beam decreases, and the signal noise ratio decreases. This causes deterioration in quantitativity and measurement accuracy of a fine structure of a semiconductor device, particularly if electrical characteristics are to be measured in a radio-frequency band. Alternatively, if the accumulation time of the detection signal is increased to improve the signal noise ratio, the measurement throughput is reduced.

Therefore, the inventors focused on a photoexcited emission electron source (hereinafter referred to as a photocathode). A photocathode, which uses electrons emitted by light irradiation, can easily shorten the pulse of an electron beam by pulsing excitation light. That is, no blanker is necessary for the pulsing, so that the irradiation current amount is not reduced due to the pulsing. In particular, electrons emitted from a photocathode using gallium arsenide (GaAs), which is a p-type semiconductor whose surface has a negative electron affinity (NEA), can generate a pulse electron beam of about 10 picoseconds at the shortest, and can be used as a high-brightness short-pulse electron source about the same as that of a Schottky field emission electron source.

An object of the invention is to provide a technique for using a photocathode having the electron emission characteristics as described above as an electron source of an SEM and using a high-brightness short-pulse electron beam to enable measurement of a high-speed variation in time of a surface voltage of a sample, thereby measuring a time constant of a measurement region with a high spatial resolution of, for example, about 10 nm and a high time resolution of, for example, 1 nanosecond or less.

### Solution to Problem

An electron beam application device according to an embodiment of the invention includes: a sample stage configured to allow a sample to be placed; an electron optical system including a pulse electron gun and configured to focusing, on the sample, a pulse electron beam emitted from the pulse electron gun; a detector configured to detect signal electrons emitted when the sample is irradiated with the pulse electron beam; a probe configured to come into contact with a measurement region of the sample; a voltage source configured to apply a periodically varying sample voltage to the sample via the probe; a timing controller configured to synchronously control the voltage source and the pulse electron gun and control a timing of the irradiation with the pulse electron beam in one period of the sample voltage; and a control system. The pulse electron gun includes a first excitation light source configured to generate pulse excitation light, a photocathode including a transparent substrate and a photoelectric film, a condensing lens disposed between the first excitation light source and the transparent substrate and configured to condense the pulse excitation light transmitted through the transparent substrate onto the photoelectric film, and an anode electrode configured to accelerate and emit the pulse electron beam emitted from a condensing position of the photoelectric film. The control system calculates a time constant of the measurement region of the sample on the basis of a detection signal amount resulting from the detector detecting signal electrons emitted when the measurement region to which the sample voltage is applied is irradiated with the pulse electron beam.

### Advantageous Effects of Invention

The time constant of a device sample having a nanoscale fine structure or pattern can be measured in a wide range from nanoseconds to microseconds. Other technical problems and novel features will become apparent from descriptions of the present description and the accompanying drawings.

### BRIEF DESCRIPTION OF DRAWINGS

FIG. 1 is a diagram illustrating the outline of an electron beam application device using an SEM.

FIG. 2 is a diagram schematically illustrating a pulse electron gun.

FIG. 3 is a diagram illustrating the respective waveforms of a sample voltage Vₛ and a pulse electron beam.

FIG. 4 is a diagram illustrating the energy distribution of electrons emitted by irradiation with an electron beam.

FIG. 5 is a diagram illustrating the trajectory of secondary electrons (SE) when a positive voltage is applied to a sample.

FIG. 6 is a diagram illustrating the energy distribution of secondary electrons (SE) detected when a positive voltage is applied to the sample.

FIG. 7 is a diagram illustrating a method for measuring a time constant of a measurement region of the sample.

FIG. 8 is a diagram illustrating a change in time of a detection signal amount I_{det} when the measurement region to which a sample voltage Vₛ as a pulse voltage is applied is irradiated with the pulse electron beam at a timing Δt.

FIG. 9 is a diagram illustrating a timing Δt dependency of the detection signal amount I_{det}.

FIG. 10 is a flowchart of a measurement procedure according to Embodiment 1.

FIG. 11 is a diagram illustrating a voltage waveform of a sine waveform applied to the sample as a periodically varying voltage.

FIG. 12 is a diagram illustrating a voltage waveform of a square waveform applied to the sample as the periodically varying voltage.

FIG. 13 is a diagram illustrating a voltage waveform of a triangular waveform applied to the sample as a periodically varying voltage.

FIG. 14 is a diagram illustrating a voltage waveform of a sawtooth waveform applied to the sample as a periodically varying voltage.

FIG. 15 is a diagram illustrating a voltage waveform of a sawtooth waveform applied to the sample as a periodically varying voltage.

FIG. 16 is a diagram illustrating a change in time of the detection signal amount I_{det} when the measurement region to which the sample voltage Vₛ as a low-frequency sine voltage is applied is irradiated with the pulse electron beam at the timing Δt.

FIG. 17 is a diagram illustrating a change in time of the detection signal amount I_{det} when the measurement region to which the sample voltage Vₛ as a high-frequency sine voltage is applied is irradiated with the pulse electron beam at the timing Δt.

FIG. 18 is a diagram illustrating a frequency f dependency of the amplitude of the detection signal amount I_{det}.

FIG. 19 is a flowchart of a measurement procedure according to Embodiment 2.

FIG. 20 is a diagram illustrating a configuration example of a voltage source using a photodetector.

### DESCRIPTION OF EMBODIMENTS

Hereinafter, embodiments of the invention will be described in detail with reference to the drawings.

### Embodiment 1

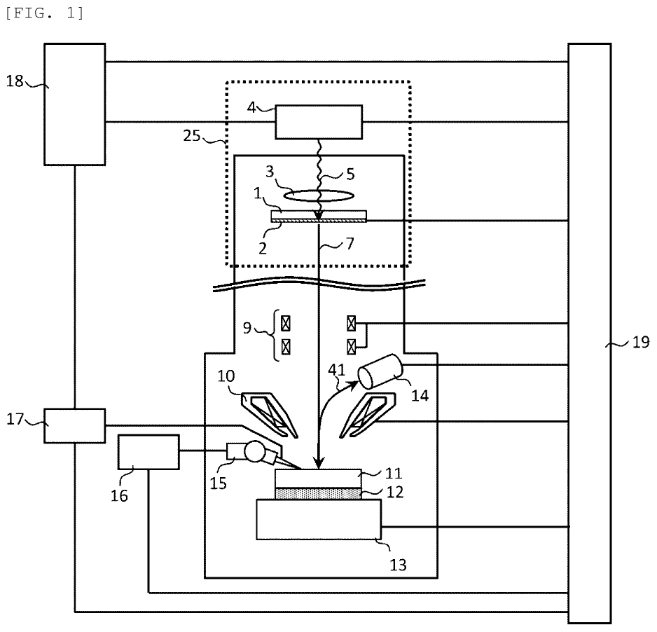

FIG. 1 illustrates a configuration example of an electron beam application device using a scanning electron microscope (SEM) according to the present embodiment. As a pulse electron gun 25 mounted on the SEM, a photocathode for emitting electrons by irradiation with an excitation light 5 is used. A pulse electron beam 7 emitted from the photocathode is focused on a sample 11 by an electron optical system of the SEM. In addition to the pulse electron gun 25, the electron optical system of the SEM includes: an aperture (not illustrated) for limiting the diameter of the pulse electron beam 7; electron lenses such as a condenser lens and an objective lens 10 for focusing the pulse electron beam 7 on the sample 11; and a deflector 9 for scanning the sample with the focused pulse electron beam 7. The sample 11 is placed on a sample stage 13 for moving the measurement region thereof into a region irradiated with the pulse electron beam 7. A fine probe 15 is brought into contact with the sample 11, and a periodically varying sample voltage from a voltage source 17 is applied to a local region of the sample 11 via the probe 15. In order to avoid a short circuit between the sample 11 and the sample stage 13, the sample 11 is placed on the sample stage 13 via an insulator 12. With the irradiation of the pulse electron beam 7, signal electrons 41 emitted from the sample 11 are detected by the detector 14.

The timing controller 18 synchronously controls the pulse electron gun 25 and the voltage source 17 for generating a periodically varying sample voltage, and controls the timing (phase or delay time) of the irradiation of the sample with the pulse electron beam 7 in one period of the sample voltage. The control system 19 sets measurement conditions of the electron beam application device and controls the components of the electron beam application device according to the measurement conditions. The time constant of the measurement region is calculated on the basis of the measurement result. The control system 19 includes a computer and a controller provided for the components of the electron beam application device. In accordance with an instruction from the computer, the controller controls the operation of the corresponding component. The computer includes an arithmetic device, an input device, and a display device. The arithmetic device controls the units of the electron beam application device according to the measurement conditions, and performs arithmetic processing based on the detection signal from the detector 14. Such control and arithmetic processing are implemented as programs in advance in the computer. Further, although not illustrated, a vacuum exhaust facility is also provided for maintaining the inside of the mirror body of the SEM in a vacuum state.

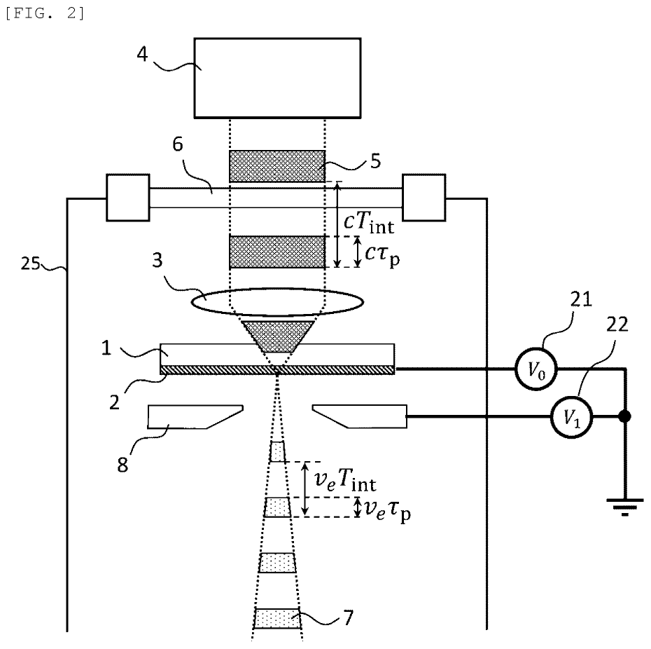

FIG. 2 illustrates a configuration example of the pulse electron gun 25. Here, a case where a high-intensity photocathode using gallium arsenide (GaAs), which is a p-type semiconductor, formed on a transparent substrate is used as an electron source will be described as an example, but a photocathode having a different configuration may be used. The pulse electron gun 25 includes: a photocathode having a transparent substrate 1 and a photoelectric film 2 formed thereon; a condensing lens 3; an anode electrode 8 for accelerating and emitting an electron beam generated from the photoelectric film 2; and a vacuum evacuation facility (not illustrated) for maintaining the periphery of the photoelectric film 2 at an extremely high vacuum. An acceleration voltage (cathode voltage) V₀ 21 is applied to the photoelectric film 2, and an extraction voltage V₁ 22 is applied to the anode electrode 8. The extraction voltage V₁ 22 may be a ground potential. The photoelectric film 2 is provided in a vacuum chamber together with the condensing lens 3, and the excitation light 5 emitted from the excitation light source 4 provided outside the vacuum chamber passes through the viewing port 6 and is condensed to the photoelectric film 2 by the condensing lens 3 provided on a back surface of the photoelectric film 2. The electron beam emitted from the condensing position is used as an electron beam of the SEM.

Since the source size of the electron source is inversely proportional to the square root of the brightness of the electron source, if a low-brightness electron source is used, it is difficult to focus the irradiation electron beam diameter of the SEM to 10 nm or less due to the limitation of the light source diameter. Therefore, a high-brightness electron source is essential for obtaining a high spatial resolution on the order of nm in SEM observation. An example of a preferable electron source of a high-brightness photoexcitation system is a high-brightness photoelectric film using p-type GaAs having an NEA surface. As illustrated in FIG. 2, if the condensing lens 3 is disposed in the vicinity of the back side of the photoelectric film 2 serving as an electron emission surface, the excitation light 5 transmitting through the transparent substrate 1 can be condensed with a large numerical aperture (NA) of 0.5 or more. The condensing diameter of the excitation light having a wavelength λ condensed on the photoelectric film 2 by the condensing lens 3 having the numerical aperture NA is about λ/NA.

When the surface of the photoelectric film 2 is NEA activated, the energy level at the lower end of the conduction band in the photoelectric film 2 becomes an energy level higher than the vacuum level. Accordingly, electrons excited from the valence band to the conduction band by the irradiation with the excitation light 5 are efficiently emitted from the inside of the photoelectric film 2 to the vacuum region. If p-type GaAs is used as the active layer of the photoelectric film 2, the effective mass of electrons emitted with the irradiation of excitation light is as small as 0.067 times the static mass of electrons in the vacuum, and thus the electron emission angle when emitted to the vacuum region is as small as about 10 degrees or less. As a result, the pulsed excitation light 5 is condensed on the photoelectric film 2, and the electron emission region is reduced to about σ 1 μm to form a point source, thereby obtaining a pulse electron gun 25 whose electron source has a peak brightness of about the same as that of a Schottky electron source (about 10⁷A/m²/sr/V). The pulse width of the pulse electron beam 7 emitted from the p-type GaAs having an NEA surface can be set to about 10 picoseconds at the shortest by setting the excitation light 5 to short-pulse light.

A pulse width τₚ and a period Tᵢₙₜ (the reciprocal of the frequency f) of the pulse electron beam 7 are controlled by the excitation light source 4 for emitting the excitation light 5. The relationship between the pulse width and the period of the pulse electron beam 7 is τₚ<Tᵢₙₜ, and the range of the duty ratio defined as the ratio (τₚ/Tᵢₙₜ) between the pulse width and the period depends on the excitation light source 4. Since the pulse waveform of the excitation light 5 is the pulse waveform of the pulse electron beam 7, an excitation light source 4 having appropriate wavelength λ, pulse width τₚ, period Tᵢₙₜ, duty ratio, and peak intensity is used to obtain the necessary irradiation performance of the pulse electron beam 7.

In FIG. 2, the spatial pulse length in the traveling direction of the pulsed light used as the excitation light 5 is cτₚ (c is the speed of light, c=3.0×10⁸ m/s). On the other hand, a velocity vₑ of the pulse electron beam 7 of an energy E₀ emitted to the vacuum region can be calculated from the equation of vₑ=√(2E₀/mₑ), which is derived from the relational expression of the energy of electron, where the static mass of electron mₑ=9.1×10⁻³¹ kg. Therefore, the spatial pulse length in the traveling direction of the pulse electron beam 7 is vₑτₚ. Since vₑ<<c assuming an irradiation condition of an energy of 30 keV or less used in a general SEM, the spatial pulse length of the electron beam is shorter than that of the excitation light.

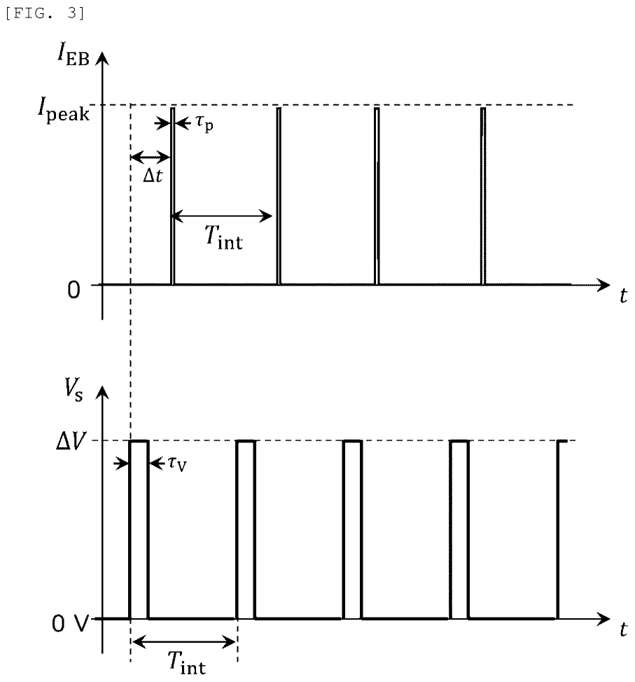

In Embodiment 1, the time constant of the sample 11 is measured by applying a rectangular pulse voltage having a pulse width τ_{V} and a period Tᵢₙₜ illustrated in FIG. 3 as the periodically varying voltage to the sample 11 via the fine probe 15. As the voltage source 17 for applying the rectangular pulse voltage to the sample 11, for example, a function generator can be used. Other voltage sources may be used as long as they can output the same rectangular pulse voltage. Considering the need to measure the potential change of the sample 11, the pulse waveform of the pulse electron beam 7 is set such that the pulse width τₚ of the pulse electron beam 7 is sufficiently smaller than the pulse width τ_{V} of the pulse voltage applied to the sample 11 (τₚ<<τ_{V}) . Although the pulse waveform of the pulse electron beam 7 is illustrated as a rectangular waveform in FIG. 3, the pulse waveform of the pulse electron beam 7 is not limited to the shape of the waveform, and a waveform such as a waveform having a bell-shaped peak may be used, as long as the magnitude relationship of the pulse width (τₚ<τ_{V}) is satisfied.

The probe 15 is preferably a needle-shaped probe having a tip diameter of 100 nm or less so as to come into contact with a minute region on the sample 11. Further, in order to bring the probe 15 into contact with any position on the sample 11 while observing the measurement region with the SEM, a drive mechanism of the probe 15 is installed in the sample chamber of the SEM so that the tip position of the probe 15 can be controlled independently of the sample position control by the sample stage 13. The drive mechanism of the probe 15 receives power supply from a control power supply 16 installed in an atmospheric region. FIG. 1 illustrates the configuration of an SEM including one probe 15, but two or more probes 15 may be mounted. By mounting a plurality of probes 15, it is possible to use the measurement function of a normal SEM probing device, and it is possible to compare or calibrate the measurement result of the time constant measured by the two-terminal method by the probing device and the measurement result of the time constant measured by the synchronous control and the timing control of the periodically varying voltage and the pulse electron beam 7 via the probe 15 according to the present embodiment. If the photocathode has a high brightness characteristic about the same as that of a Schottky electron source (about 10⁷A/m²/sr/V), an irradiation beam diameter on the order of nm can be obtained under optimum conditions by appropriately selecting the working distance between the objective lens 10 of the SEM and the sample 11, and the irradiation energy of the pulse electron beam 7.

The signal electrons 41 to be detected by the detector 14 are low-energy secondary electrons (SE). The energy of the electron beam with which the SEM irradiates the sample 11 can be set freely, but if the irradiation energy is set to around 1 keV, the yield of the SEs 41 emitted from the sample 11 increases, which is preferable from the viewpoint of the signal noise ratio. It is known that the energy width of the electron beam emitted from the photoelectric film 2 having an NEA surface is as small as 0.2 eV or less. Therefore, if the SEM is to be used under an irradiation condition with small irradiation energy, the configuration of the present embodiment in which the photoelectric film 2 having a small influence of chromatic aberration, which is a limitation on the irradiation beam diameter, is used as an electron source is a superior device structure in terms of measurement accuracy.

Further, the present embodiment describes a configuration example in which a semi-in-lens objective lens, which is capable of obtaining superior irradiation performance and SE discrimination detection performance in a low acceleration region, is applied as the objective lens 10. However, the same measurement is also possible if an objective lens other than semi-in-lens is applied, such as an out-lens objective lens or an objective lens applied with a boosting method of applying a positive voltage of about 10 kV to a cylindrical electrode to pass a magnetic field lens region of an out-lens objective lens at a high speed. The semi-in-lens objective lens has a high degree of spatial freedom on the sample side, and thus is an advantageous mode of objective lens in that a sufficient space for placing the probe 15 for measurement can be secured. In addition, the semi-in-lens objective lens can shorten the focal length and can reduce the axial aberration such as the spherical aberration and the chromatic aberration by leaking the lens magnetic field to the sample 11, and thus is advantageous in obtaining the irradiation beam diameter on the order of nm particularly under the irradiation condition of low irradiation energy. The low-energy SEs 41 generated on the sample 11 are focused by the lens magnetic field leaked onto the sample 11, and are transported above the objective lens 10. The SEs 41 can be efficiently detected by installing a deflector for off-axis deflection of the SEs 41 above the objective lens 10. The configuration of the deflector may be of the electric field type, the magnetic field type, or the Wien filter type in which the electric field and the magnetic field are arranged at right angles. In order to reduce the adverse effect on the irradiation beam, a deflector for compensation may be added closer to the electron source than the deflector for off-axis deflection of the SEs 41 to cancel out deflection aberration, which causes deterioration of the irradiation beam diameter.

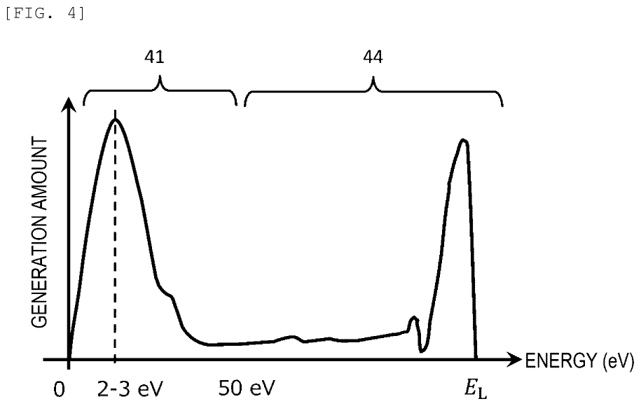

FIG. 4 illustrates the energy distribution of the electrons emitted when the sample is irradiated with an electron beam having energy E₀. In general, the SEs (signal electrons) 41 have a peak generation amount at an energy of 2 eV to 3 eV, whereas the high-energy reflected electrons (backscattered electron: BSE) 44 have a broad energy distribution with the energy E₀ of the irradiated electron beam as the maximum energy. The detector 14 for the SEs 41, which are the main detection targets, may be an Everhart & Thornley (ET) detector used as a general detector for SEM in which a scintillator, a light guide, and a photomultiplier tube (PMT) are combined. In the present embodiment, the variation in time of the detection signal is measured by applying the periodically varying voltage to the sample 11, but the response speed of the detector 14 is not necessarily high. A detector other than ET detector, such as a channeltron or a micro-channel plate (MCP), may be used as the detector 14 as long as the detector has detection sensitivity to the SEs 41.

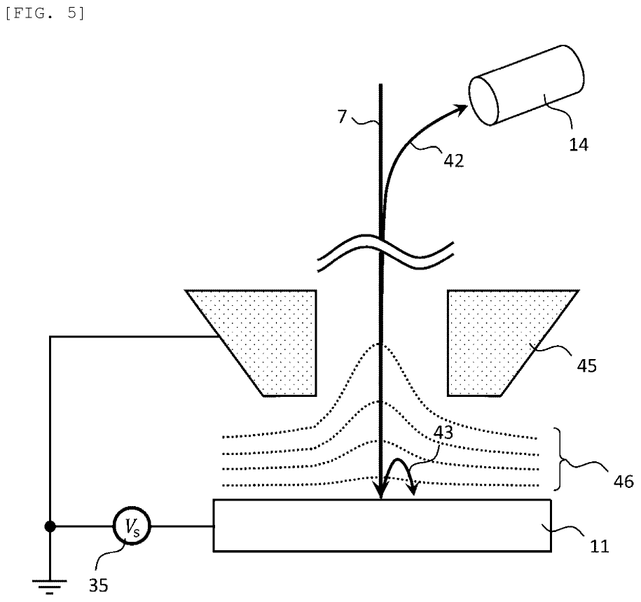

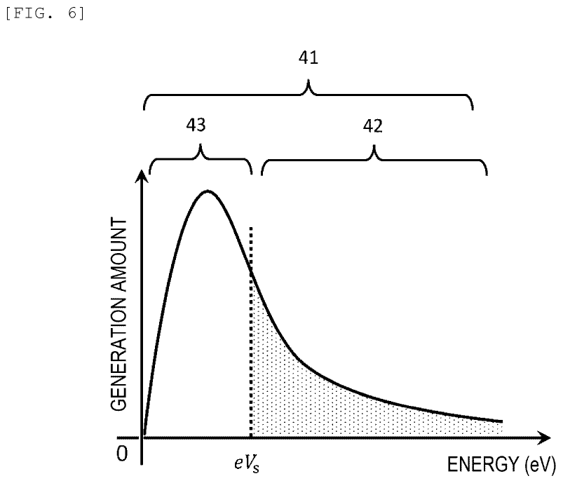

Here, if a positive voltage Vₛ (Vₛ>0 V) 35 is statically applied to the sample 11, as illustrated in FIG. 5, an electric field 46 is formed between the sample 11 and the objective lens 10 (FIG. 5 illustrates a pole piece 45 of the objective lens 10), and SEs 43 having an energy of eVₛ or less on the sample 11 are pulled back onto the sample 11. Therefore, among the SEs 41 emitted from the sample, the SEs 43 having energy equal to or less than eVₛ are not detected by the detector 14, and SEs 42 having energy exceeding eVₛ are detected by the detector 14. A schematic diagram of the energy band of the SEs 41 is illustrated in FIG. 6.

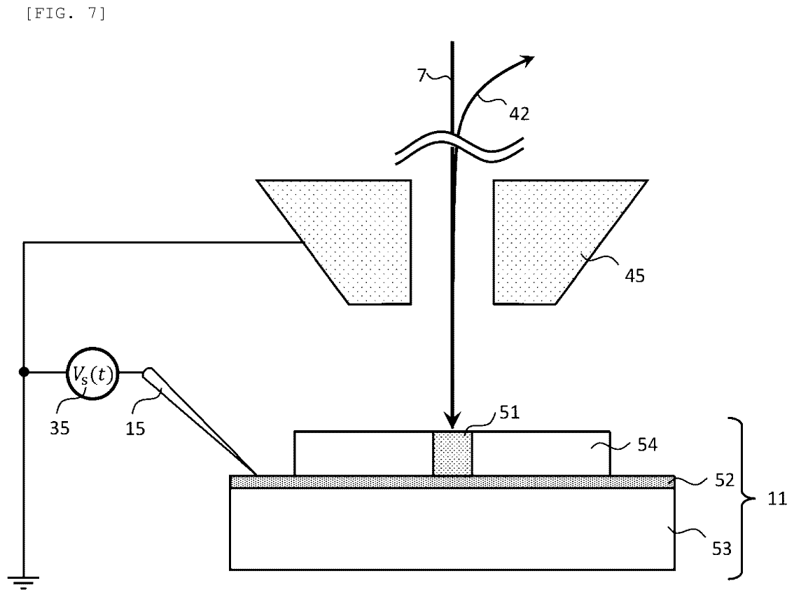

FIG. 7 illustrates a configuration example in which a rectangular pulse voltage is applied via the probe 15 to the sample 11 introduced into the SEM sample chamber to measure the time constant of a minute region caused by a resistance R and a capacity C of the sample 11. In FIG. 7, the sample 11 is displayed as a cross-sectional view. The sample 11 has a layer structure of a substrate 53, a conductor layer 52, and an insulator layer 54, and is embedded in the insulator layer 54 and provided with a plug 51 in contact with the conductor layer 52. The plug 51 exposed from the insulator layer 54 is the measurement region thereof. From the time constant of the plug 51, for example, it is possible to determine whether the plug 51 is in appropriate electrical connection with the conductor layer 52. The structure as the measurement region is not limited to the example of FIG. 7, and may be a microstructure such as an electrode of an active element such as a transistor or a plug connected to the electrode. Since the time constant can be calculated, it is possible to perform advanced determination as of whether the operation characteristics of the electronic device are satisfied in addition to simple determination as of whether the manufacture is defected.

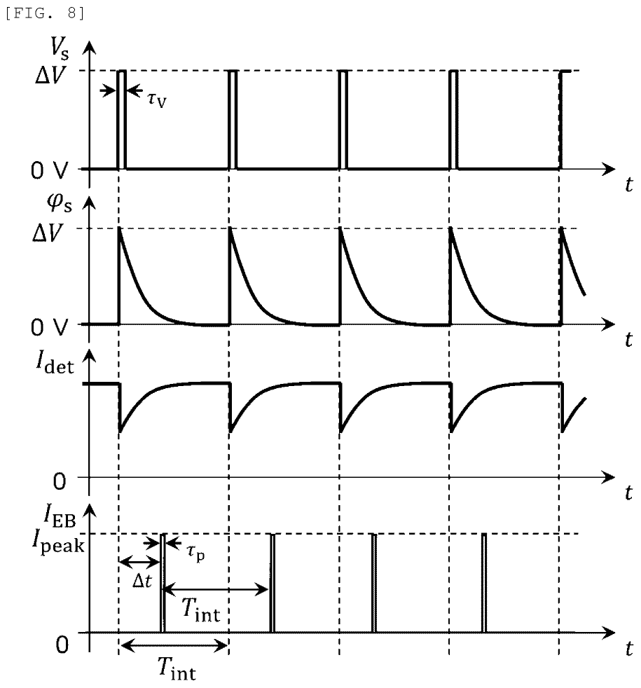

FIG. 8 illustrates the change in times in the sample voltage Vₛ, the sample surface voltage σₛ, the detection signal amount I_{det}, and the irradiation current I_{EB} of the pulse electron beam 7 when the time constant of the sample 11 is measured by applying the rectangular pulse voltage having the period Tᵢₙₜ to the sample 11. The graph of FIG. 8 corresponds to a measurement condition in which the pulse electron beam 7 is irradiated at a certain timing Δt with respect to the sample voltage Vₛ which is a periodically varying voltage. The voltage source 17 and the excitation light source 4 are synchronously controlled, and the sample voltage Vₛ and the pulse electron beam 7 of the peak intensity Iₚₑₐₖ have the same period Tᵢₙₜ. Further, the timing Δt at which the pulse electron beam 7 is irradiated in one period of the sample voltage Vₛ can be changed in a range of Δt=0 to Tᵢₙₜ by the timing controller 18. The sample surface voltage σₛ varies with the period Tᵢₙₜ due to the application of the sample voltage Vₛ, and the sample surface voltage σₛ at the timing Δt when the pulse electron beam 7 is applied to the sample 11 has the same value (however, time constant τ_{decay}<<period Tᵢₙₜ).

The pulse width to of the pulse electron beam 7 is set sufficiently smaller than the pulse width τ_{V} of the sample voltage Vₛ (τₚ<τ_{V}). The sample voltage Vₛ is a pulse voltage having a voltage amplitude ΔV (ΔV>0 V) relative to the reference voltage 0 V. Since the peak of the generation amount of SEs is near 2 eV to 3 eV, a sufficient change in the detection signal amount I_{det} can be measured with the voltage amplitude ΔV of about 5 V. The change in the detection signal amount I_{det} increases as a larger voltage amplitude ΔV is set, so that the measurement accuracy of the time constant can be increased. However, the voltage amplitude ΔV that can be set by a general function generator decreases as the frequency of the output periodically varying voltage (=1/Tᵢₙₜ) increases. Therefore, it is necessary to select the measurement condition in consideration of the set value of the period Tᵢₙₜ and the voltage amplitude ΔV that can be output under such condition. Under the condition that the sample surface voltage σₛ is close to 0 V, the electric field 46 formed on the sample 11 becomes weak, so that most of the SEs 41 are detected by the detector 14, and the detection signal amount I_{det} increases. On the other hand, under the condition that the sample surface voltage σₛ is close to the peak voltage ΔV, some of the SEs 41 are pulled back to the sample 11, so that the detection signal amount I_{det} decreases and the intensity change as illustrated in the graph of FIG. 8 is obtained.

When the periodically varying voltage Vₛ is applied to the sample 11, an electric field lens is formed between the sample 11 and the objective lens 10, and the intensity of the electric field lens varies in time at the same period as the periodically varying voltage Vₛ. It should be noted that the focus state of the pulse electron beam 7 on the sample 11 varies in time accordingly. If the size of the device region as the measurement target is sufficiently large relative to the beam diameter of the pulse electron beam 7, the change in the focus state due to the voltage variation does not cause a severe problem. On the other hand, if the size of the device region as the measurement target has a microstructure on the order of nm equivalent to the beam diameter of the pulse electron beam 7, the pulse electron beam 7 is irradiated to a region other than the device region as the measurement target due to a change in the focusing condition of the pulse electron beam 7, which makes desired measurement difficult. In order to avoid this problem, a lens for focus compensation is mounted on the path of the pulse electron beam 7 of the electron optical system of the SEM, and the lens intensity is synchronously controlled with the voltage source 17 and the pulse electron beam 7, so that a mechanism for maintaining the focus state on the sample 11 can be added to accurately measure the time constant of the microstructure.

In the measurement of the present embodiment, it is important to accurately measure the change in the detection signal amount I_{det} due to the change in the timing Δt. In order to accurately measure the change in the detection signal amount I_{det}, it is important that the irradiation current I_{EB} of the pulse electron beam 7 irradiating the sample 11 is controlled to be stable or at a constant value. If the stability of the irradiation performance of the pulse electron gun 25 becomes a problem in measurement, the irradiation current I_{EB} to the sample 11 on the path of the pulse electron beam 7 is measured every time the set value of the timing Δt is changed, and the detection signal amount I_{det} of the SEs 41 is normalized by the current value of the measured irradiation current I_{EB}, so that the reliability of the measurement result can be improved.

When the sample voltage Vₛ, which is a periodically varying voltage, is applied to the measurement region having the electrical resistance R and the capacity C, the sample surface voltage σₛ exhibits a behavior of relaxing with a time constant corresponding to the product of the electrical resistance R and the capacity C. At the timing Δt, the SE signal amount corresponding to the sample surface voltage σₛ at that moment is detected. The SE signal amount emitted with the irradiation of one pulse of the electron beam decreases as the pulse width τₚ of the pulse electron beam 7 decreases. By irradiating a plurality of pulse electron beams 7 and integrating the detection signals to obtain a sufficient signal amount, the change in time of the detection signal amount I_{det} can be measured with a sufficient signal noise ratio.

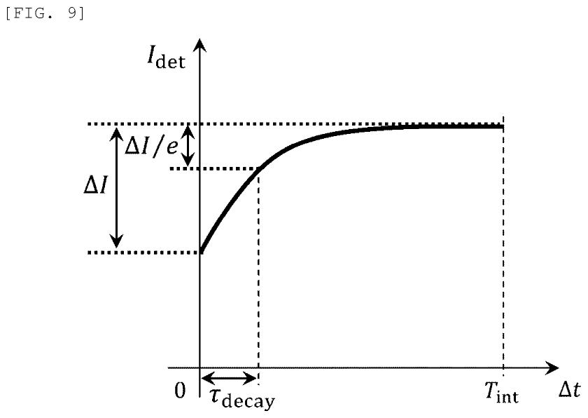

By changing the timing Δt for irradiating the pulse electron beam 7 with respect to the sample voltage Vₛ in the range of Δt=0 to Tᵢₙₜ with reference to (Δt=0) the moment at which the peak voltage ΔV is applied to the sample 11, the timing dependency of the detection signal amount I_{det} can be measured. A graph as illustrated in FIG. 9 is obtained by plotting the variation in time of the detection signal amount I_{det} according to the sample surface voltage σₛ illustrated in FIG. 8 with respect to the timing Δt. The relaxation behavior of the sample surface voltage σₛ is reflected in the variation in time of the detection signal amount I_{det}. Therefore, the time constant τ_{decay} of the measurement region can be measured by measuring the time until the detection signal amount I_{det} increases by ΔI (1-1/e), where ΔI is the signal variation amount until the detection signal amount I_{det} is saturated from the reference timing (Δt=0) in FIG. 9. The time constant τ_{decay} is calculated by performing measurement with an appropriate number of measurement points in the range of Δt=0 to Tᵢₙₜ and fitting the measurement points of the detection signal amount I_{det}. This measurement method is a measurement method applying the pump-probe method, which is often used in the optical field. Therefore, the response speed of the detection system is not necessarily high, and the time resolution of the measurement system and the accuracy of the measurement result are determined depending on the control accuracy of the voltage source 17 and the timing controller 18 for performing timing control for irradiating the synchronously controlled pulse electron beam 7.

If the electrical resistance R and the capacity C of the measurement target are known, the period Tᵢₙₜ with which the detection signal amount I_{det} is sufficiently saturated is set according to the time constant τ_{decay}=R×C. On the other hand, if the electrical resistance R and the capacity C of the measurement target are unknown and the sample 11 to be measured has a large time constant τ_{decay}, it is necessary to set a sufficiently long period Tᵢₙₜ. It should be noted that for a sample having a large time constant τ_{decay}, it is necessary to set a large period Tᵢₙₜ, and the time required to obtain the measurement result of the time constant becomes long. As the detection signal amount I_{det}, the signal amount of the measurement region may be obtained by point irradiation of the pulse electron beam 7, or the signal amount of the measurement region may be obtained from a strobe SEM image obtained by scanning the sample 11 with the pulse electron beam 7.

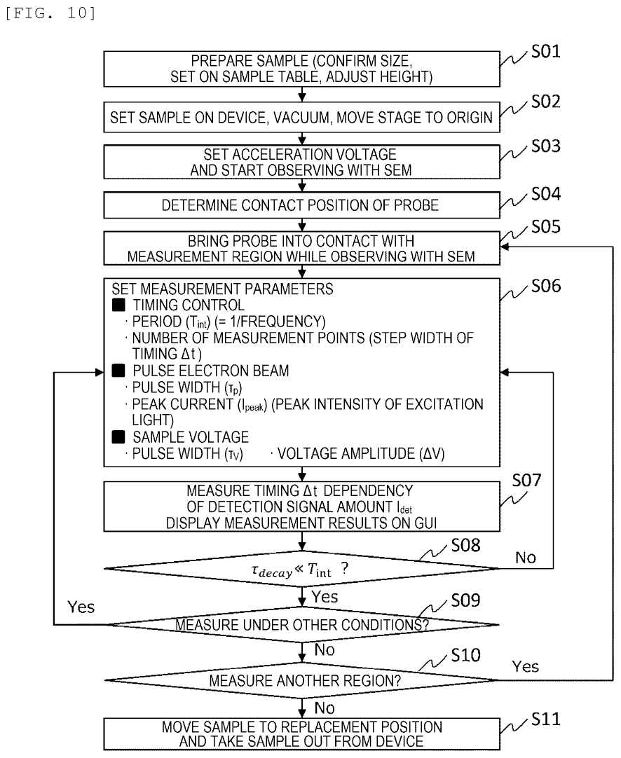

An example of the measurement procedure according to Embodiment 1 is summarized in FIG. 10 as a flowchart. Steps S01 to S03 are normal SEM observation procedures, and the electron beam irradiating the sample 11 is not necessarily pulsed. The contact position of the probe is determined (S04), and the probe 15 is brought into contact with the measurement region on the basis of the SEM image to accurately bring the probe 15 into contact with the microstructure of the sample 11 (S05). Subsequently, measurement parameters for specifying the measurement conditions for measuring the time constant of the microstructure are set (S06). The measurement parameters are as described above, and include the period Tᵢₙₜ, the number of measurement points, the pulse width τₚ of the pulse electron beam 7, the peak current Iₚₑₐₖ, the pulse width τᵥ of the sample voltage Vₛ, and the voltage amplitude ΔV. The timing Δt dependency of the detection signal amount I_{det} is measured, and the measurement result as illustrated in FIG. 9 is displayed on a GUI (S07). If the measured time constant τ_{decay} is sufficiently smaller than the period Tᵢₙₜ (YES in S08), the measurement condition can be regarded as appropriate. Otherwise (NO in S08), the measurement condition is inappropriate, and thus the measurement parameter is reset. If the same measurement region is to be measured under other measurement conditions (YES in S09), the time constant is measured while setting measurement parameters designating the other measurement conditions. Further, if the time constant of another measurement region is to be measured (YES in S10), the probe 15 is brought into contact with the other measurement region, and the time constant is measured while setting measurement parameters for designating the measurement conditions. When the measurement of all the measurement regions of the sample 11 is completed, the sample 11 is taken out from the device (S11). By the above measurement method, the time constant of the measurement region on the sample 11 can be measured in a wide range from nanoseconds to microseconds.

### Embodiment 2

In the following, Embodiment 2 will describe a procedure of measuring a time constant of a minute measurement region due to the resistance R and the capacity C of the sample 11 introduced into the sample chamber on the basis of a change in the amplitude of the detection signal amount I_{det} when the sample voltage Vₛ, which is a periodically varying voltage having a plurality of frequencies, is applied to the sample 11 via the probe 15. A device structure for performing measurement according to Embodiment 2 is the same as the device structure of Embodiment 1 illustrated in FIG. 1, and the mounted pulse electron gun 25 is the same as the configuration of Embodiment 1 illustrated in FIG. 2. The differences from Embodiment 1 are the sample voltage Vₛ applied to the sample 11, the control method thereof, and the analysis method, and the details thereof will be disclosed below.

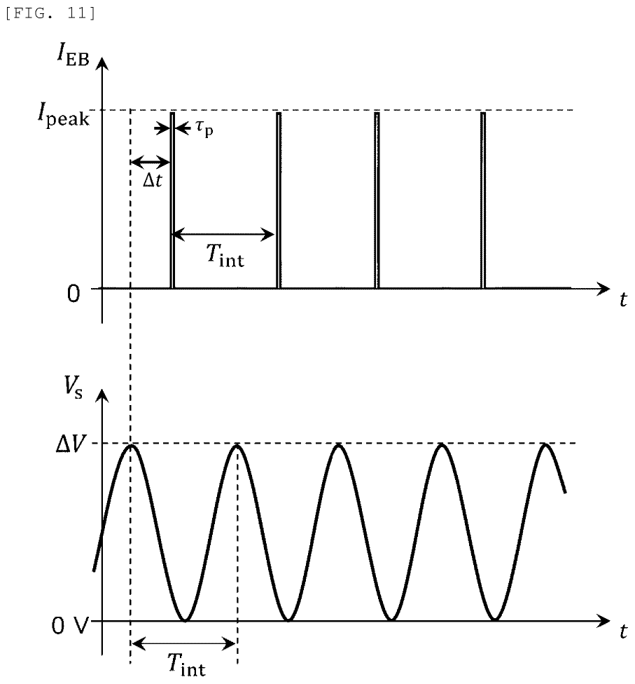

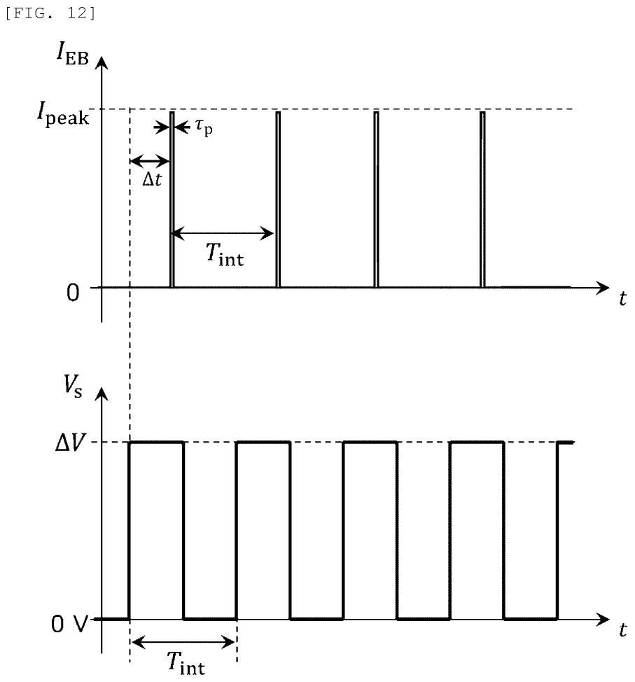

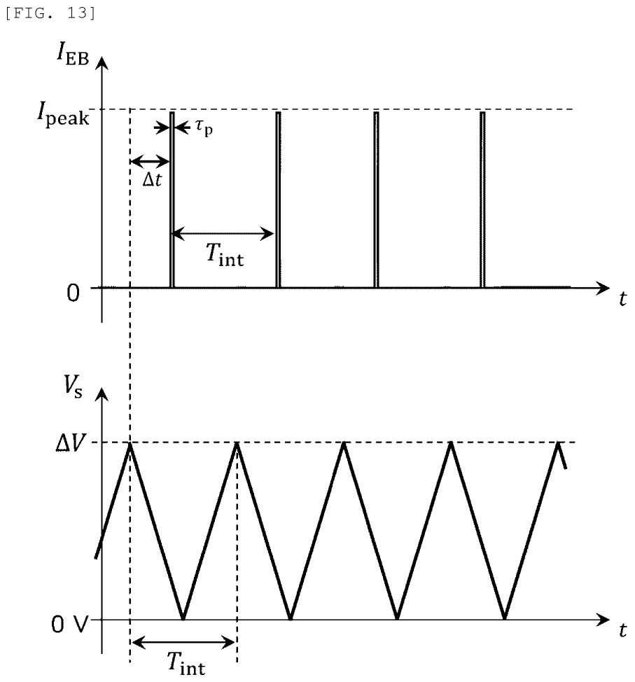

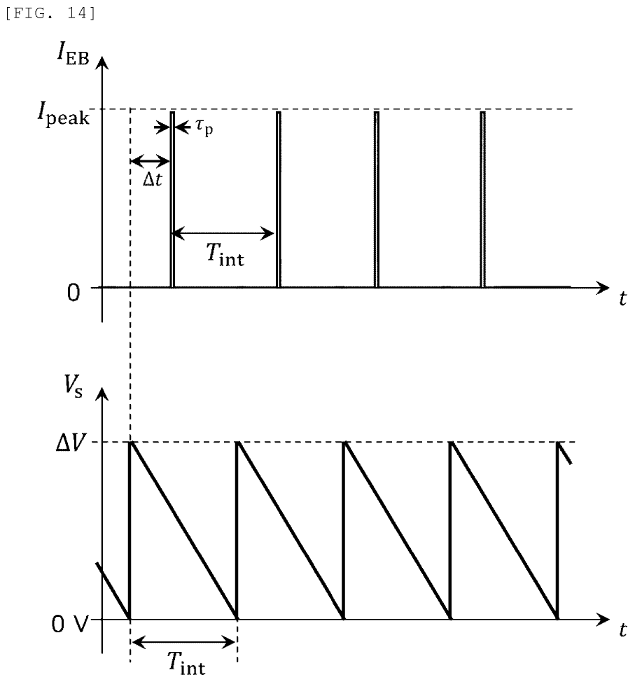

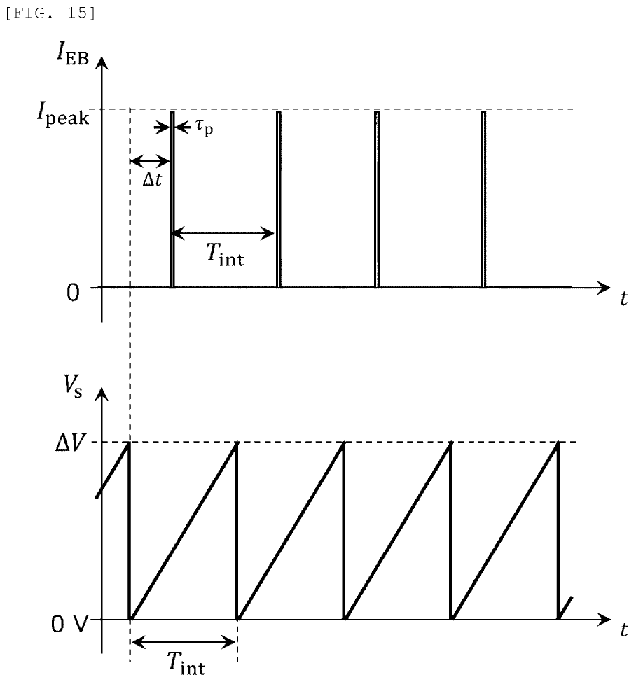

As the voltage waveform of the sample voltage Vₛ applied to the sample 11, a sine wave (FIG. 11), a square wave (FIG. 12), a triangular wave (FIG. 13), a sawtooth wave (FIGS. 14 and 15), or the like can be used in addition to the pulse voltage illustrated in Embodiment 1 (FIG. 3). The sample voltage Vₛ is not limited to the waveforms described above, and may be any periodically varying voltage as long as the waveform varies with a constant period. Here, a case where a voltage of a sine waveform is applied as the sample voltage Vₛ will be described, but the measurement principle is the same if another waveform is used.

As described above, since the peak of the generation amount of SEs 41 is near 2 eV to 3 eV, a sufficient change in the detection signal amount I_{det} can be measured with the voltage amplitude ΔV of about 5 V. The change in the detection signal amount I_{det} increases as a larger voltage amplitude ΔV is set, so that the measurement accuracy of the time constant can be increased. However, the voltage amplitude ΔV that can be set by a general function generator decreases as the frequency of the output periodically varying voltage (=1/Tᵢₙₜ) increases. Therefore, it is necessary to select the measurement condition in consideration of the set value of the period Tᵢₙₜ and the voltage amplitude ΔV that can be output under such condition. In the present embodiment, since it is necessary to measure the signal amount change at a plurality of frequencies, it is preferable to measure the voltage amplitude ΔV under the same condition even if the measurement is performed at different frequencies (1/Tᵢₙₜ). For example, if the voltage amplitude ΔV that can be set under the high-frequency condition is 5 V at the maximum and the voltage amplitude ΔV that can be set under the low-frequency condition is 10 V at the maximum, it is preferable to perform measurement at the voltage amplitude ΔV of 5 V under all the measurement conditions.

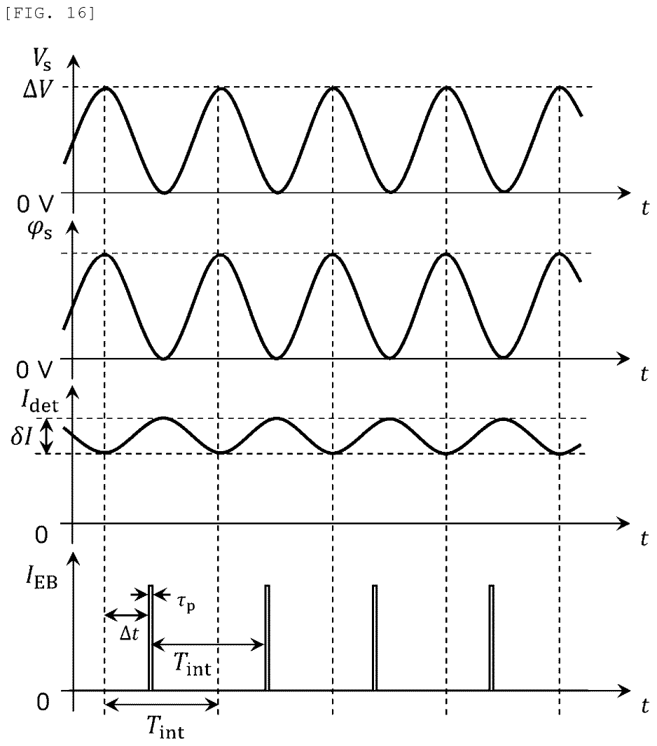

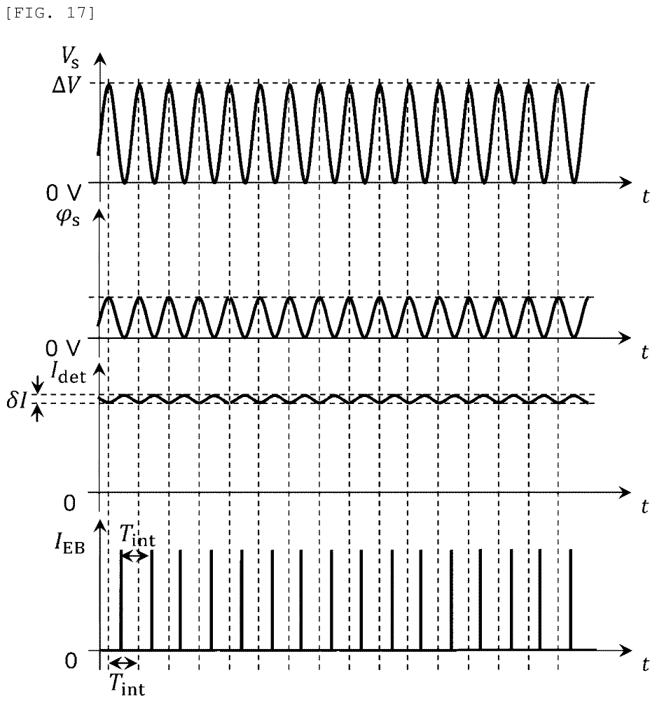

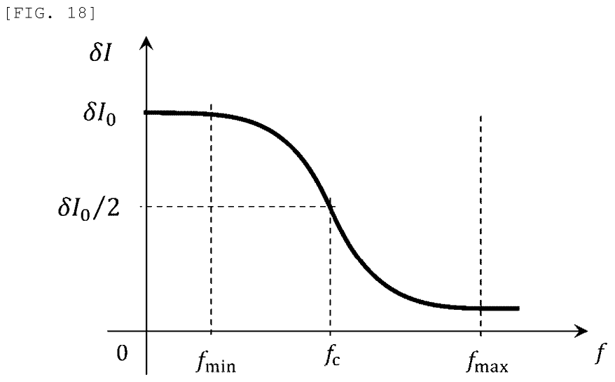

If periodically varying voltages of a plurality of frequencies are applied to the measurement region having the electrical resistance R and the capacity C, the same potential variation as that of the applied sample voltage Vₛ is observed in the sample surface voltage σₛ under a condition of a sufficiently small frequency. However, as the frequency increases, the filter characteristics due to the electrical resistance R and the capacity C are observed, and if a periodically varying voltage having a high frequency is applied, no potential variation is observed in the sample surface voltage σₛ, or the amplitude of the potential variation decreases. This situation is schematically illustrated in FIGS. 16 and 17. FIG. 16 corresponds to the low-frequency condition, and FIG. 17 corresponds to the high-frequency condition. Under the high-frequency condition, the amplitude δI of the detection signal amount I_{det} decreases. Therefore, a graph as illustrated in FIG. 18 is obtained by plotting the amplitude δI of the detection signal amount I_{det} with respect to the frequency f of the periodically varying voltage Vₛ. Regarding such a change in the graph, the time constant τ_{decay} of the measurement region can be calculated as 1/(2πf_{c}) from a relational expression between the frequency f and the time constant τ_{decay}, where a cutoff frequency f_{c} is a frequency at which a amplitude δI₀ of the detection signal amount I_{det} under a sufficiently low-frequency condition becomes a half.

In order to measure the amplitude δI of the detection signal amount I_{det} for each measurement condition of different frequencies f, it is necessary to set the timing Δt such that the change in the detection signal amount I_{det} for one period can be measured. In the case of Embodiment 2, considering that a change in phase occurs together with a change in amplitude, the timing Δt is set such that the number of measurement points is about 5 to 10 in the range of Δt=0 to Tᵢₙₜ for each frequency f to be measured, and the amplitude δI of the detection signal amount I_{det} for each frequency f is measured from the measured detection signal amount I_{det}. Similarly to Embodiment 1, in the measurement of Embodiment 2, it is important to accurately measure the change in the detection signal amount I_{det} due to the change in the timing Δt. In order to accurately measure the change in the detection signal amount I_{det}, it is important that the irradiation current I_{EB} of the pulse electron beam irradiating the sample 11 is controlled to be stable or at a constant value. If the stability of the irradiation performance of the pulse electron gun 25 becomes a problem in measurement, the irradiation current I_{EB} to the sample 11 on the path of the pulse electron beam 7 is measured every time the set value of the timing Δt is changed, and the detection signal amount I_{det} of the SEs 41 is normalized by the current value of the measured irradiation current I_{EB}, so that the reliability of the measurement result can be improved. Further, as the detection signal amount I_{det}, the signal amount of the measurement region may be obtained by point irradiation of the pulse electron beam 7, or the signal amount of the measurement region may be obtained from a strobe SEM image obtained by scanning the sample 11 with the pulse electron beam 7.

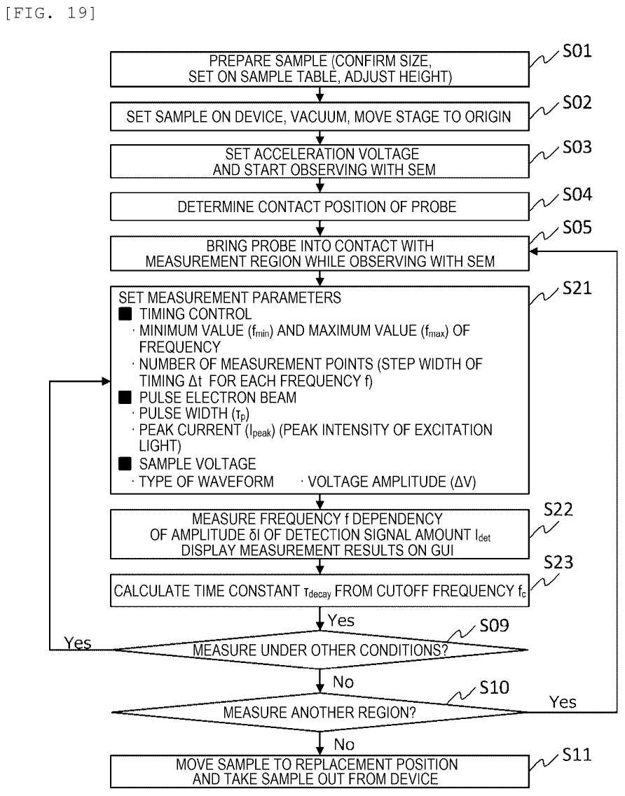

An example of the measurement procedure according to Embodiment 2 is summarized in FIG. 19 as a flowchart. The same procedures as those in the flowchart of Embodiment 1 (FIG. 10) are denoted by the same reference signs, and redundant description is omitted. In step S21, measurement parameters for specifying the measurement conditions for measuring the time constant of the microstructure are set. The measurement parameters are as described above, and include the range of the frequency f to be changed (a minimum value fₘᵢₙ and a maximum value fₘₐₓ), the number of measurement points, the pulse width τₚ of the pulse electron beam 7, the peak current Iₚₑₐₖ, the type of waveform of the sample voltage Vₛ, and the voltage amplitude ΔV. The frequency f dependency of the amplitude δI of the detection signal amount I_{det} is measured, and the measurement result as illustrated in FIG. 18 is displayed on the GUI (S22). The time constant τ_{decay} is calculated from the cutoff frequency f_{c} obtained as the measurement result (S23). By the above measurement method, the time constant of the measurement region on the sample 11 can be measured in a wide range from nanoseconds to microseconds.

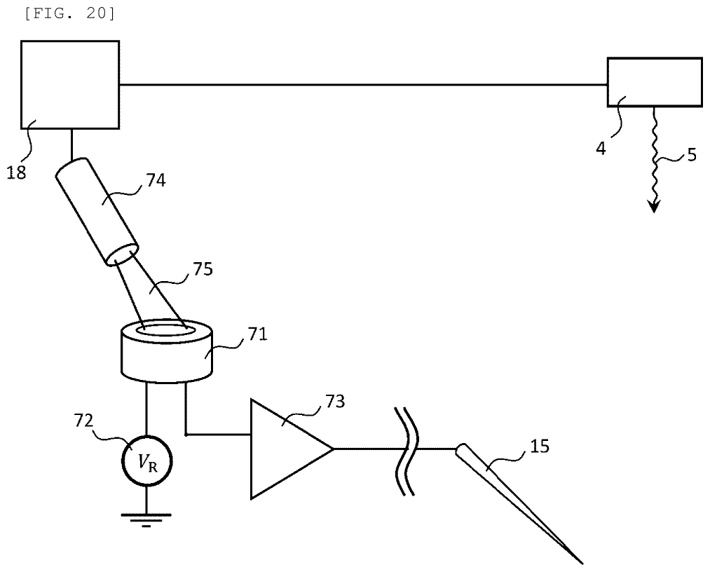

In Embodiment 1 and Embodiment 2, a function generator is exemplified as the voltage source 17 for applying the periodically varying voltage to the sample 11, but the present invention is not limited thereto. FIG. 20 illustrates a configuration example of the voltage source 17 for generating a periodically varying voltage using a voltage output of a photodetector.

A photodetector 71 having a time resolution of about nanoseconds and a high response speed may be an avalanche photodiode (APD). An APD may have a reduced parasitic capacitance by applying a reverse bias V_{R} 72, and thus is capable of high-speed operation. Excitation light 75 emitted from an excitation light source 74 for generating a periodically varying voltage is irradiated to the photodetector 71 with appropriately set intensity and period. The generated current signal of electron-hole pairs is amplified by an amplifier 73 by voltage conversion to be used as the sample voltage Vₛ.

The photodetector 71 or the amplifier 73 may be mounted in a sample chamber in which the sample 11 is placed, or may be installed in an atmospheric region and connected to the probe 15 via a feedthrough. The excitation light source 74 for generating the periodically varying voltage and the excitation light source 4 of the photoelectric film 2 serving as the generation source of the pulse electron beam 7 are connected to the timing controller 18, so as to synchronously control the sample voltage Vₛ applied to the sample 11 and the timing of the pulse electron beam 7 applied to the sample 11. As described above, the output of the photodetector 71 illustrated in FIG. 20 can be used as the periodically varying voltage in Embodiment 1 or Embodiment 2.

The invention is not limited to the above embodiments, and includes various modifications. For example, the embodiment and the modification described above have been described in detail to facilitate understanding of the invention, and the invention is not necessarily limited to those including all the configurations described above. A part of the configuration of one embodiment and modification can be replaced with the configuration of another embodiment and modification, and the configuration of another embodiment and modification can be added to the configuration of one embodiment and modification. A part of a configuration in each of the embodiments and the modification may be added to, deleted from, or replaced with another configuration.

### Reference Signs List

1: transparent substrate
2: photoelectric film
3: condensing lens
4: excitation light source
5: excitation light
6: viewing port
7: pulse electron beam
8: anode electrode
9: deflector
10: objective lens
11: sample
12: insulator
13: sample stage
14: detector
15: probe
16: control power supply
17: voltage source
18: timing controller
19: control system
21: acceleration voltage (cathode voltage)
22: extraction voltage
25: pulse electron gun
35: sample voltage
41 ,42, 43: secondary electron (SE)
44: reflected electrons (BSE)
45: pole piece
46: electric field
51: plug
52: conductor layer
53: substrate
54: insulator layer
71: photodetector
72: reverse bias
73: amplifier
74: excitation light source
75: excitation light

1. An electron beam application device comprising:
a sample stage configured to allow a sample to be placed;
an electron optical system including a pulse electron gun and configured to focusing, on the sample, a pulse electron beam emitted from the pulse electron gun;
a detector configured to detect signal electrons emitted when the sample is irradiated with the pulse electron beam;
a probe configured to come into contact with a measurement region of the sample;
a voltage source configured to apply a periodically varying sample voltage to the sample via the probe;
a timing controller configured to synchronously control the voltage source and the pulse electron gun and control a timing of the irradiation with the pulse electron beam in one period of the sample voltage; and
a control system, wherein
the pulse electron gun includes
a first excitation light source configured to generate pulse excitation light,
a photocathode including a transparent substrate and a photoelectric film,
a condensing lens disposed between the first excitation light source and the transparent substrate and configured to condense the pulse excitation light transmitted through the transparent substrate onto the photoelectric film, and
an anode electrode configured to accelerate and emit the pulse electron beam emitted from a condensing position of the photoelectric film, and
the control system calculates a time constant of the measurement region of the sample on the basis of a detection signal amount resulting from the detector detecting signal electrons emitted when the measurement region to which the sample voltage is applied is irradiated with the pulse electron beam.

2. The electron beam application device according to claim 1, wherein
the voltage source applies the sample voltage having a pulse waveform to the sample, and
the control system
causes the voltage source to apply the sample voltage of a predetermined period to the measurement region of the sample,
measures a timing dependency of the detection signal amount by causing the timing controller to change the timing of the irradiation with the pulse electron beam in one period of the sample voltage, and
calculates the time constant of the measurement region of the sample from the measured timing dependency of the detection signal amount.

3. The electron beam application device according to claim 1, wherein
the control system
applies the sample voltage of a plurality of frequencies to the measurement region of the sample,
measures a frequency dependency of an amplitude of the detection signal amount which varies due to the periodic variation of the sample voltage, and
calculates the time constant of the measurement region of the sample from the measured frequency dependency of the amplitude of the detection signal amount.

4. The electron beam application device according to claim 3, wherein
the sample voltage has any one of a pulse waveform, a sine waveform, a square waveform, a triangular waveform, and a sawtooth waveform.

5. The electron beam application device according to claim 1, wherein
the photoelectric film is a semiconductor whose surface has a negative electron affinity.

6. The electron beam application device according to claim 1, wherein
the electron optical system includes a focus compensation lens configured to compensate for a variation in time of a focus state of the pulse electron beam due to the application of the sample voltage to the sample, and
a lens intensity of the focus compensation lens is controlled to be synchronized with the sample voltage.

7. The electron beam application device according to claim 1, wherein
the voltage source includes
a second excitation light source configured to generate excitation light whose intensity varies periodically,
a photodetector configured to be irradiated with the excitation light from the second excitation light source, and
an amplifier configured to amplify a current signal from the photodetector by voltage conversion, and
the timing controller synchronously controls the second excitation light source of the voltage source and the first excitation light source of the pulse electron gun.

8. A time constant measurement method using an electron beam application device, the electron beam application device including:
a sample stage configured to allow a sample to be placed;
an electron optical system including a pulse electron gun and configured to focusing, on the sample, a pulse electron beam emitted from the pulse electron gun;
a detector configured to detect signal electrons emitted when the sample is irradiated with the pulse electron beam;
a probe configured to come into contact with a measurement region of the sample;
a voltage source configured to apply a periodically varying sample voltage to the sample via the probe;
a timing controller configured to synchronously control the voltage source and the pulse electron gun and control a timing of the irradiation with the pulse electron beam in one period of the sample voltage; and
a control system,
the pulse electron gun including:
a first excitation light source configured to generate pulse excitation light,
a photocathode including a transparent substrate and a photoelectric film,
a condensing lens disposed between the first excitation light source and the transparent substrate and configured to condense the pulse excitation light transmitted through the transparent substrate onto the photoelectric film, and
an anode electrode configured to accelerate and emit the pulse electron beam emitted from a condensing position of the photoelectric film,
the detector detecting signal electrons emitted when the measurement region to which the sample voltage is applied is irradiated with the pulse electron beam; and
the control system calculating a time constant of the measurement region of the sample on the basis of the detection signal amount resulting from the detection by the detector.

9. The time constant measurement method according to claim 8, wherein
the voltage source applies the sample voltage having a pulse waveform to the sample, and
the control system
causes the voltage source to apply the sample voltage of a predetermined period to the measurement region of the sample,
measures a timing dependency of the detection signal amount by causing the timing controller to change the timing of the irradiation with the pulse electron beam in one period of the sample voltage, and
calculates the time constant of the measurement region of the sample from the measured timing dependency of the detection signal amount.

10. The time constant measurement method according to claim 8, wherein
the control system
applies the sample voltage of a plurality of frequencies to the measurement region of the sample,
measures a frequency dependency of an amplitude of the detection signal amount which varies due to the periodic variation of the sample voltage, and
calculates the time constant of the measurement region of the sample from the measured frequency dependency of the amplitude of the detection signal amount.

11. The time constant measurement method according to claim 10, wherein
the sample voltage has any one of a pulse waveform, a sine waveform, a square waveform, a triangular waveform, and a sawtooth waveform.
